(19) United States
(12) Patent Application Publication
(10) Pub. No.: US 2026/0002988 A1
(43) Pub. Date: Jan. 1, 2026

(54) Monitoring and Control of Advance Die-to-Die Interconnect Lanes

(71) Applicant: Intel Corporation, Santa Clara, CA (US)

(72) Inventors: Sambaran MITRA, Barasat (IN); Swapnil Shashank GAUTAM, Bangalore (IN); Neethumol O U, Bangalore (IN); Lokuprasanth S, Erode (IN); Raja Vignesh K, Naganathapura (IN)

(21) Appl. No.: 18/755,761

(22) Filed: Jun. 27, 2024

(51) Int. Cl. G01R 31/317

(52) U.S. Cl. CPC G01R 31/31717

(57) ABSTRACT

In the various aspects, the present SoC package uses advanced die-to-die (D2D) interconnects having extra or spare lanes that, when any faulty lane(s) is uncovered during a dynamic HVM health check/testing phase, may be available as a substitute/replacement, or available for load sharing on a rotational basis. The present system and method also provide for an initial HVM health check, i.e., Sort/Class, that will include various tests to determine the working and non-working lanes of the D2D interconnects. In an aspect, when the SoC package is operational, i.e., in functional mode, the extra working lanes are not “fused” by the die-to-die interconnect IP. The present lane controller logic modules may be provided to check and change the lanes dynamically, i.e., as part of the dynamic health check, which can significantly help increase the lifetime of the whole SoC chips/package.

### BACKGROUND

For integrated circuit design and fabrication, the need to improve performance and lower costs are constant challenges. There is an increasing trend to integrate and package multiple dice into a system-on-chip (SoC), which is driven by yield considerations, i.e. cost, as well as by the need to integrate proprietary functionality from different sources into the SoC. Semiconductor manufacturers may use innovative interconnect and packaging technologies, including 2.5D and 3D variants. In such semiconductor packages, the die-to-die interfaces may be used to connect two or more dies inside the package to take advantage of very short channels or lanes to achieve power efficiency and very high bandwidth efficiency, beyond what traditional chip-to-chip interfaces may be able to achieve.

Presently, the detection of faulty or non-working lanes is typically conducted only during testing or a health check for high-volume manufacturing (HVM). It may be possible to repair a faulty lane, or if not, the faulty line may be “fused” at the HVM health check stage. Once fusing is performed, the working lanes may not be changed during runtime. Moreover, if a lane goes “bad” during runtime, the chip needs to be discarded even though healthy lines are available on the chip. In addition, when all lanes are working, there may be “extra” or spare lanes that remain inactive or unused for the lifetime of the chip, and the electrical stress will be placed only on the “active” lanes. Such distribution of electrical stress resulting from the use of certain lines, while leaving other healthy lines unstressed, may lead to a lower than optimal life duration of an SoC package.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows an exemplary representation of a schematic view of a conventional device with a system-on-chip package;

FIG. 2 shows an exemplary representation of a schematic view of a conventional die-to-die interconnect;

FIG. 3 shows an exemplary representation of a schematic view of a die-to-die interconnect according to an aspect of the present disclosure;

FIG. 4 shows an exemplary representation of a schematic view of a die-to-die interconnect according to another aspect of the present disclosure;

FIG. 5 shows an exemplary representation of a schematic view of a die-to-die interconnect according to yet another aspect of the present disclosure;

FIG. 6 shows a simplified flow diagram for an exemplary execution sequence for an initial HVM health check according to an aspect of the present disclosure;

FIG. 7 shows a simplified flow diagram for an exemplary execution sequence for a dynamic health check according to yet another aspect of the present disclosure;

FIG. 8 shows an exemplary representation of a schematic view for a lane controller logic according to an aspect of the present disclosure; and

FIG. 9 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

According to the present disclosure, a present SoC package or other chip package using advanced die-to-die (D2D) interconnects will have extra or spare lanes that, when any faulty lane(s) is uncovered during an HVM health check/testing phase, may be available as a substitute/replacement or for load sharing on a rotational basis. The present testing system and method provide for an initial HVM health check, i.e., Sort/Class, that will include various tests to determine the working and non-working lanes of the D2D interconnects. In an aspect, when the SoC package is operational, i.e., in functional mode, the extra working lanes are not “fused” or discarded by the die-to-die interconnect IP, i.e., rendered unavailable for use, but rather can be used. The present lane controller logic modules may be provided to check and change the lanes dynamically, i.e., as part of a dynamic health check/testing, which can significantly help increase the lifetime of the whole SoC chips package and other packages. In another aspect, these extra lanes may be used to increase the life of the SoC package by compensating for any runtime lane damage or used in an iterative cyclical manner to reduce the stress on any one particular lane.

The present disclosure provides a testing system including a first health check module disposed on a first die and a second health check module disposed on a second die, for which the first die and the second die have a die-to-die interconnect disposed therebetween. In an aspect, the first and second health check modules are configured to perform an initial health check testing of the die-to-die interconnect for working lanes and non-working lanes during high-volume manufacturing of a chip package, which contains the first and second dies. In an aspect, a first logic circuit disposed on the first die and a second logic circuit disposed on the second die, for which the first logic circuit and the second logic circuit are coupled to the die-to-die interconnect, and are configured to perform a dynamic health check/testing of the die-to-die interconnect for working lanes and faulty lanes during operation of the chip package. In another aspect, the first health check module and the second health check module may be components of the die-to-die interconnect IP boxes of the first and second dies, respectively. In another aspect, the testing system may include external components; for example, hardware and/or software residing on manufacturing tools.

The present disclosure further provides a system-on-chip package including a first die, a second die, and a die-to-die interconnect disposed between the first die and the second die. In an aspect, a health check module is configured to provide a health check result for the die-to-die interconnect during high-volume manufacturing, for which health check result indicates working and non-working lanes for the die-to-die interconnect, for which the first die comprises a first logic circuit coupled to the die-to-die interconnect, and the second die comprises a second logic circuit coupled to the die-to-die interconnect, for which the first and second logic circuits are configured to perform a dynamic testing of the die-to-die interconnect for working lanes and faulty lanes during an operation of the system-on-chip package. In an aspect, the first and second logic circuits are further configured to provide instructions that are stored in a non-transitory memory device to control use of the working lanes of the die-to-die interconnect.

The present disclosure is also directed to a method that provides a system-on-chip package using a high-volume manufacturing process, for which the system-on-chip package includes a first die and a second die, and with a die-to-die interconnect disposed therebetween. In an aspect, the first die has a first health check module and a first logic circuit, also called a first lane controller logic module, and the second die has a second health check module and a second logic circuit, also called the second lane controller logic module.

The method further includes performing an initial health check on the die-to-die interconnect during the high-volume manufacturing process using the first and second health check modules, for which the initial health check includes an initial testing of the die-to-die interconnect to determine which are working lanes and non-working lanes, if any, and obtaining an initial health check result identifying and indicating numbers for working and non-working lanes, and placing the initial health check result in a health check result register.

In addition, the method further includes performing a dynamic health check/testing on the die-to-die interconnect during an operation of the system-on-chip package using the first and second logic circuits, for which the dynamic health check includes a periodic testing of the die-to-die interconnect to determine working lanes and faulty lanes in the die-to-die interconnect and obtaining an updated health check result identifying and indicating numbers for working and faulty lanes, and placing the updated health check result in the health check result register.

The technical advantages of the present disclosure include, but are not limited to:
(i) providing a health check scheme that improves the control and management of die-to-die interconnects;
(ii) optimizing the usage of the working lanes of die-to-die interconnects by distributing the operational load over all of the working lanes; and
(iii) enhancing the life of chip packages that may have one or more lanes become faulty during runtime.

To more readily understand and put into practical effect the present system-on-chip (SoC) packages and method for monitoring and controlling the lanes of the die-to-die interconnects used therein, which may provide improved manufacturing yields, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

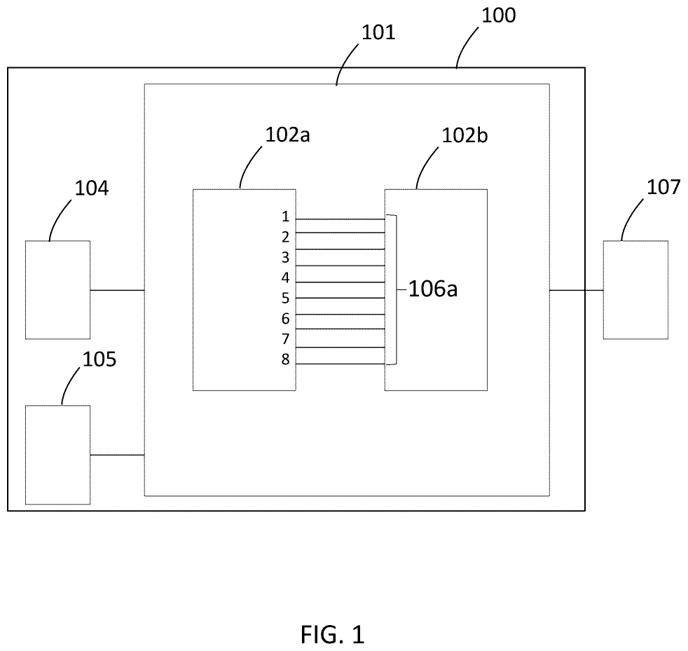

FIG. 1 shows an exemplary representation of a schematic view of a conventional semiconductor component 100, e.g., a printed circuit board, with a conventional system-on-chip package (SoC) 101 disposed thereon. In this aspect, the SoC 101 may include a first die 102a and a second die 102b, and a plurality of lanes 106a of a die-to-die interconnect disposed between the first die 102a and the second die 102b. The plurality of lanes 106a may be provided by a variety of conventional technologies; for example, an embedded multi-die interconnect bridge (EMIB), chip-on-wafer-on-substrate (CoWoS) interconnects for stacked chips, and optical fiber communication (OFC) interconnects.

The SoC 101 may be coupled to a peripheral component interconnect express (PCIe) 104, a memory device 105, e.g., a DRAM, and a display unit 107. The PCLe 104 is a hardware interface used in computers for connecting peripheral devices such as storage drives and graphics cards. In an aspect, the SoC 101 may be production tested by a high-volume manufacturing (HVM) process that includes a Sort or Class process, which acts as a “health” check during the production of SoC packages to test and remove defective or faulty packages.

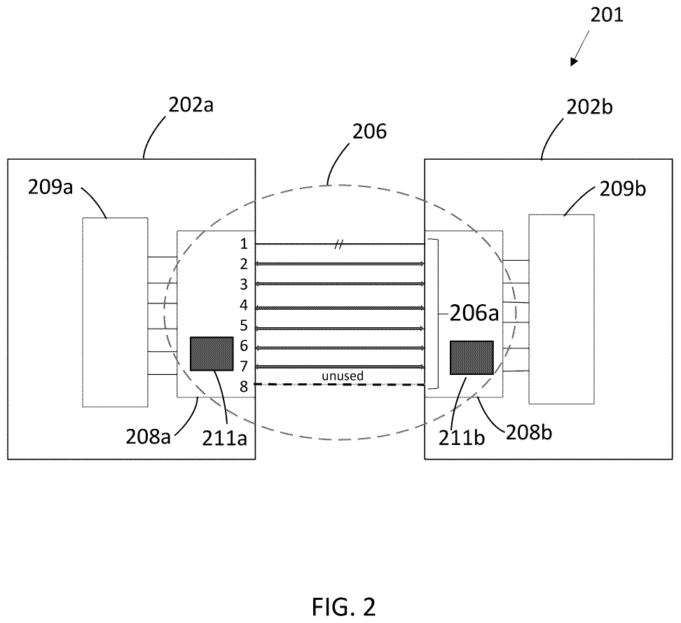

FIG. 2 shows an exemplary representation of a schematic view of a conventional die-to-die interconnect. In this aspect, a SoC 201 may include a first die 202a and a second die 202b, and a die-to-die interconnect 206 having a plurality of lanes 206a, e.g., eight (8) lanes, disposed between the first die 202a and the second die 202b. The die-to-die interconnect 206 may include a first die-to-die interconnect IP box 208a, for the first die 202a, and a second die-to-die interconnect IP box 208b, for the second die 202b, which IP boxes may each include a controller, a memory device and other components.

The die-to-die interconnect IP boxes 208a and 208b may use a variety of conventional protocols; for example, universal chiplet interconnect express (UCIe), which is an open specification for a die-to-die interconnect and serial bus between chiplets, and multi-die input/output (MDIO), which is a serial bus used to manage physical layer devices. In addition, the die-to-die interconnect IP boxes 208a and 208b may be coupled to system boxes (SBO) 209a and 209b, respectively, which is a controller that provides system-level protocols that manage the data traffic sent to die-to-die interconnects. The SBOs 209a and 209b may be further connected to an SoC level agent (not shown) that provides the protocol or IP for the SoC.

The first die 202a and the second die 202b may include multiplexers and/or switching circuits (not shown), which are components of the die-to-die interconnect IP boxes 208a and 208b, that route signals for data communications and control applications using the plurality of lanes 206a. The plurality of lanes 206a may, for example, have a faulty or non-working lane 1 and working lanes 2 through 8 that are detected during an HVM health check that may be performed by a first health check module 211a and a second health check module 211b, which provide logic circuits that work together with the hardware and software of the die-to-die interconnect IP boxes 208a and 208b, respectively. When the die-to-die interconnect 206 requires only six working lanes, lanes 2 through 7 may be designated for use by the die-to-die interconnect IP boxes 208a and 208b, while both lane 1 (non-working lane) and lane 8 (working but unused) may be “discard”, i.e., rendered unavailable for use.

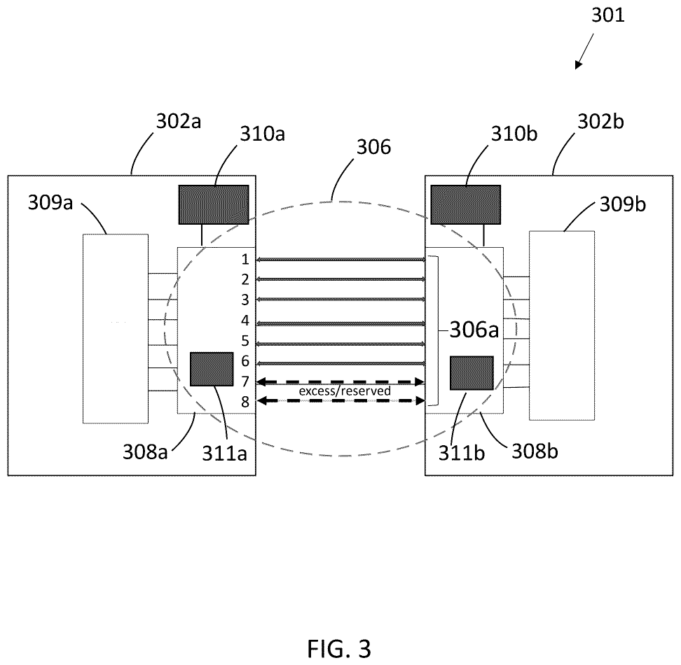

FIG. 3 shows an exemplary representation of a schematic view of a die-to-die interconnect according to an aspect of the present disclosure. In this aspect, a chip package 301 may include a first die 302a and a second die 302b, and a die-to-die interconnect 306 having a plurality of lanes 306a, e.g., eight (8) lanes, disposed between the first die 302a and the second die 302b. The plurality of lanes 306a may be provided by a variety of conventional technologies; for example, an EMIB, OFC interconnects and other types of interconnects. In another aspect, the die-to-die interconnect 306 requires only six (6) working lanes. It should be understood that the chip package 301 may be a SoC package or another type of multi-die package.

In this aspect, the die-to-die interconnect 306 may include a first die-to-die interconnect IP box 308a, for the first die 302a, and a second die-to-die interconnect IP box 308b, for the second die 302b, which IP boxes may each include a controller, a memory device and other components. The die-to-die interconnect IP boxes 308a and 308b may use a variety of conventional protocols; for example, UCIe, MDIO, and other types of protocols to manage the physical layer devices.

In addition, the die-to-die interconnect IP boxes 308a and 308b may be coupled to SBO 309a and 309b, respectively, which is a controller that provides system protocols that manage the data traffic sent die-to-die interconnects, and lane controller logic modules 310a and 310ba (also called first and second logic circuits) may be used to provide a dynamic health check or dynamic testing, which may be performed during the runtime operation of the chip package 301 in a device (not shown).

In another aspect, lane controller logic modules 310a and 310ba may also assist in performing an initial HVM health check together with a first health check module 311a and a second health check module 311b, which provide logic circuits that work together with the hardware and software of the die-to-die interconnect IP boxes 308a and 308b, respectively. In another aspect, the first and second health check modules 311a and 311b may have components (not shown) that are disposed on the chip package 301 and not on the first and second dies 302a and 302b, respectively.

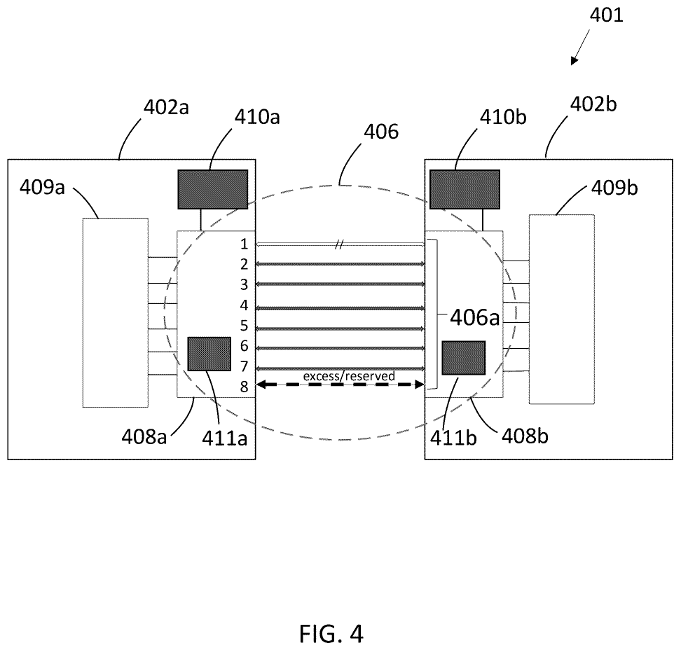

The first die 302a and the second die 302b may include multiplexers and/or switching circuits (not shown), which are components of the die-to-die interconnect IP boxes 308a and 308b, that route signs for data communications and control applications using the plurality of lanes 306a. The plurality of lanes 306a may, for example, have no faulty or non-working lanes, i.e., lanes 1 through 8 are working, as detected during an initial HVM health check. Although the die-to-die interconnect 306 requires only six (6) working lanes, lanes 1 through 6 may be initially designated for use by the die-to-die interconnect IP boxes 308a and 308b, while both lanes 7 and 8 are retained as “excess” or reserve lanes that may be used later, as discussed with FIG. 4 below. It should be understood that the number of working lanes, as well as the required lanes used, in a die-to-die interconnect may vary depending on the type of dies being connected and the applications/operations being performed thereby.

FIG. 4 shows an exemplary representation of a schematic view of a die-to-die interconnect according to another aspect of the present disclosure. In this aspect, a SoC 401 may include a first die 402a and a second die 402b, and a die-to-die interconnect 406 having a plurality of lanes 406a, e.g., eight (8) lanes, disposed between the first die 402a and the second die 402b. The plurality of lanes 406a may be provided by a variety of conventional technologies; for example, an EMIB, OFC interconnects and other types of interconnects. In another aspect, the die-to-die interconnect 406 requires only six (6) working lanes.

In this aspect, the die-to-die interconnect 406 may include a first die-to-die interconnect IP box 408a, for the first die 402a, and a second die-to-die interconnect IP box 408b, for the second die 402b, which IP boxes may each include a controller, a memory device and other components. The die-to-die interconnect IP boxes 408a and 408b may use a variety of conventional protocols; for example, UCIe, MDIO, and other types of protocols to manage the physical layer devices.

In addition, the die-to-die interconnect IP boxes 408a and 408b may be coupled to SBO 409a and 409b, respectively, which is a controller that provides system protocols that manage the data traffic sent die-to-die interconnects, and lane controller logic modules 410a and 410ba (also called first and second logic circuits) may be used to provide a dynamic health check, which may be performed during the operation of the SoC package 401 in a device (not shown).

In another aspect, lane controller logic modules 410a and 410ba may also assist in performing an initial HVM health check together with a first health check module 411a and a second health check module 411b, which provide logic circuits that work together with the hardware and software of the die-to-die interconnect IP boxes 408a and 408b, respectively. In another aspect, the health check modules 411a and 411b may have components (not shown) that are disposed on the SoC package 401 and not on the first and second dies 402a and 402b, respectively.

The plurality of lanes 406a may, for example, have no faulty or non-working lanes, i.e., lanes 1 through 8 are working, as detected during the initial HVM health check. Although the die-to-die interconnect 406 requires only six (6) working lanes, lanes 1 through 6 may be initially designated for use by the lane controller logic modules 410a and 410b, while both lanes 7 and 8 are retained as “excess” or reserve lanes. If, during the dynamic health check for the SoC 401, an initially designated lane, e.g., lane 1, is found to be faulty or non-working, a reserve lane, e.g., lane 7, may be “activated” to fulfill the six (6) lane requirement. Similarly, if during a subsequent dynamic health check for the SoC 401, a further initially designated lane is found to be faulty or non-working, the reserved lane 8 may be activated in its place by lane controller logic modules 410a and 410b.

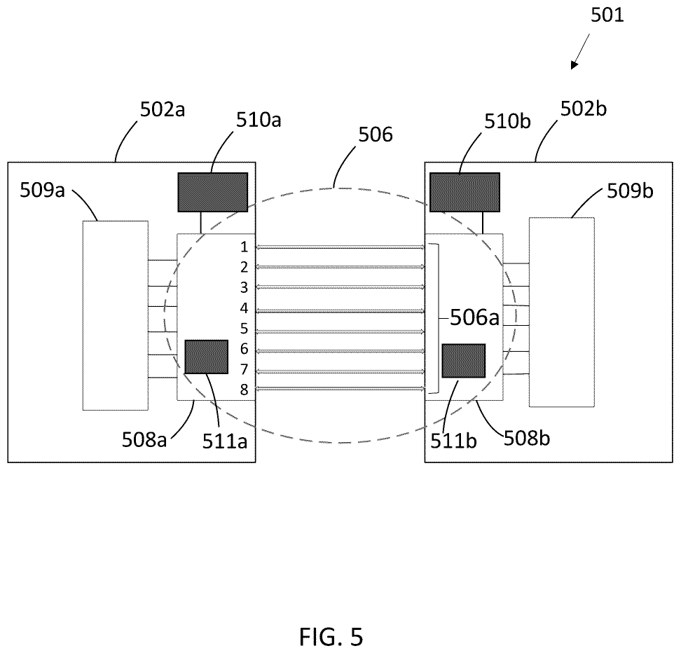

FIG. 5 shows an exemplary representation of a schematic view of a die-to-die interconnect according to yet another aspect of the present disclosure. In this aspect, a SoC 501 may include a first die 502a and a second die 502b, and a die-to-die interconnect 506 having a plurality of lanes 506a, e.g., eight (8) lanes, disposed between the first die 502a and the second die 502b. The plurality of lanes 506a may be provided by a variety of conventional technologies; for example, an EMIB, OFC interconnects and other types of interconnects. In another aspect, the die-to-die interconnect 506 requires only six (6) working lanes.

In this aspect, the die-to-die interconnect 506 may include a first die-to-die interconnect IP box 508a, for the first die 502a, and a second die-to-die interconnect IP box 508b, for the second die 502b, which IP boxes may each include a controller, a memory device and other components. The die-to-die interconnect IP boxes 508a and 508b may use a variety of conventional protocols; for example, UCIe, MDIO, and other types of protocols to manage the physical layer devices.

In addition, the die-to-die interconnect IP boxes 508a and 508b may be coupled to system boxes 509a and 509b, respectively, which provide system protocols that manage the data traffic sent die-to-die interconnect, and lane controller logic modules 510a and 510b (also called first and second logic circuits), which may assist in performing a dynamic health check and an initial HVM health check together with a first health check module 511a and a second health check module 511b, which provide logic circuits that work together with the hardware and software of the die-to-die interconnect IP boxes 508a and 508b, respectively. In another aspect, the health check modules 511a and 511b may have components (not shown) that are disposed on the SoC package 501 and not on the first and second dies 502a and 502b, respectively.

The plurality of lanes 506a may, for example, have no faulty or non-working lanes, i.e., lanes 1 through 8 are working, as detected during the initial HVM health check. Although the die-to-die interconnect 506 requires only six (6) working lanes, lanes 1 through 8 may all be initially designated for use on a rotational basis by the lane controller logic modules 510a and 510b. However, if during a subsequent dynamic health check for the SoC 501, one of the eight (8) lanes is found to be faulty or non-working, the lane controller logic modules 510a and 510b may discard the non-working lane and revise the rotational order among the remaining working lanes.

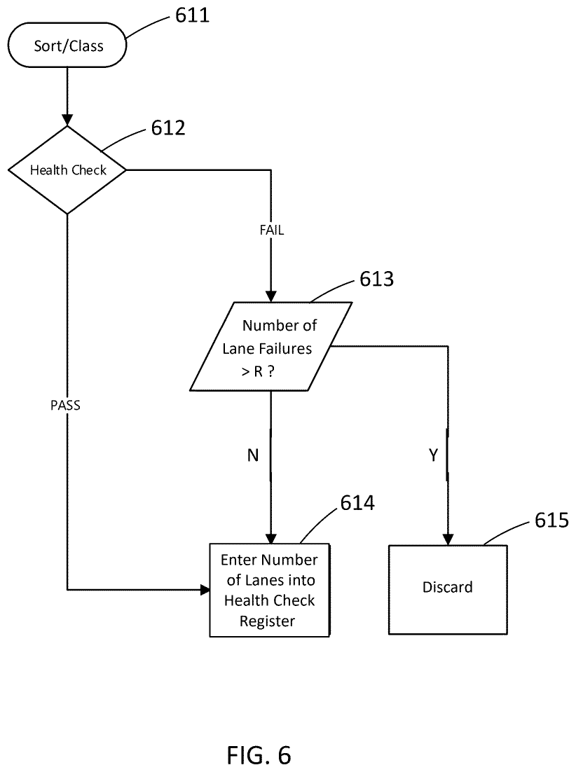

FIG. 6 shows a simplified flow diagram for an exemplary execution sequence or instructions for an initial HVM health check according to an aspect of the present disclosure. In this aspect, the flow diagram shows the activities that represent a sort/class phase of the initial HVM health check. The instructions for the initial HVM health check may be stored on a non-transitory memory device on an SoC package. As shown in FIG. 6, a Sort process is set up for a SoC package in activity 611, and the health check is conducted on all of the lanes of the die-to-die interconnects of the SoC to see if they are healthy enough to transfer data is performed in activity 612. This health check may be performed by conventional die-to-die lane detection algorithms that provide Sort and Class operations and may have two outcomes as shown. If all functional lanes are healthy, the flow moves to activity 614. However, if there are faulty or non-working lanes, the flow moves to activity 613.

In activity 613, the number of working lanes in a die-to-die interconnect (i.e., the total number of lanes minus the number of non-working lanes) is compared with the required minimum number of working lanes “R” for the die-to-die connection. If the number of working lanes is greater than or equal to the required minimum number of working lanes for the die-to-die connection, then the flow moves to activity 614. In activity 614, the number of working lanes for the die-to-die interconnect is entered or logged into a health check results register for future reference during the dynamic health check. However, if the number of working lanes is less than the required minimum number of working lanes for the die-to-die connection, then the flow moves to activity 615, which is to discard the SoC package.

For example, the possible health check outcomes for a die-to-die interconnect having a total of ten (10) lanes and a required minimum number R of eight (8) lanes using a conventional HVM health check process versus a present initial health check, in accordance with the flow diagram in FIG. 6, are shown in Table 1 below.

TABLE 1

| | | Outcomes of a Present |
|---|---|---|
| Nos. of | Outcomes of Conventional | Initial HVM Health |
| Working Lanes | HVM Health Checks | Checks |
| Less than 8 | Discard chip | Discard chip |
| working lanes | | |
| 8 working lanes | Use chip, discard 2 lanes | Use chip, discard 2 lanes |
| | (2 faulty) | (2 faulty) |
| 9 working lanes | Use chip, discard 2 lanes | Use chip, discard 1 lane |
| | (1 working, 1 faulty) | (1 faulty) |
| 10 working lanes | Use chip, discard 2 lanes | Use chip, discard no |
| | (2 working) | lanes |

For both the present initial and conventional HVM health checks, if the number of working lanes is less than eight (8) lanes, which is the R for the die-to-die interconnect, the chip package will be discarded. Similarly, when the number of working lanes is 8, the chip package will be used with eight (8) working lanes being active and two (2) fault lanes not being used. Thereafter, the present initial and conventional HVM health checks will differ.

For conventional HVM health checks, in the case of 9 working lanes, the health check protocol will use only eight (8) out of nine (9) working or good lanes, with one (1) working or healthy lane being discarded or fused. Similarly, in the case of ten (10) good lanes, there will be two (2) working or healthy lanes that will be discarded and remain unused.

For the present initial HVM health checks, when the number of working lanes is nine (9) or ten (10), the extra working lanes will either be used or kept in reserve to be used as needed during the actual working phase or runtime of an SoC package.

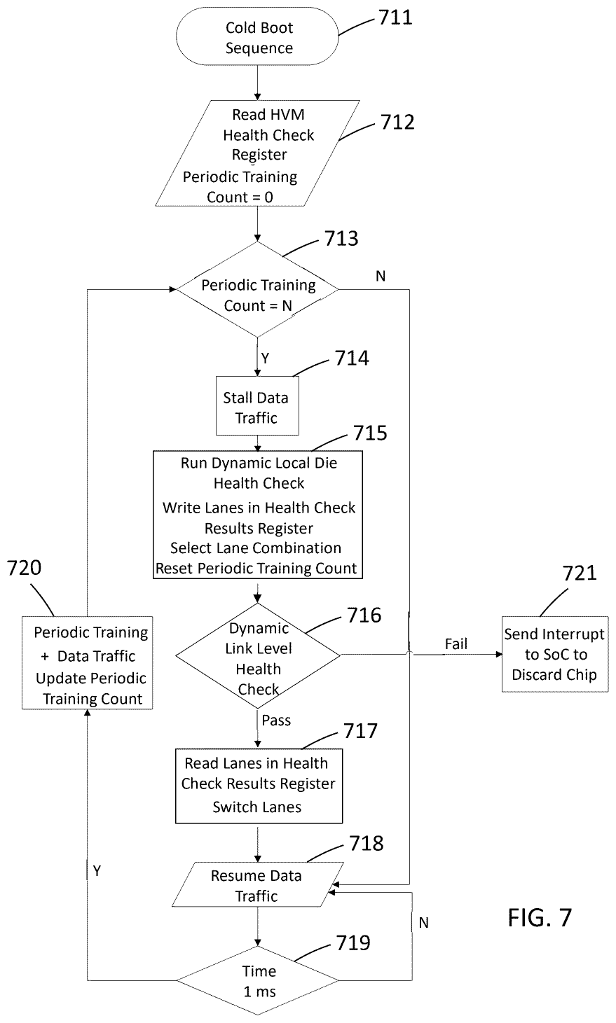

FIG. 7 shows a simplified flow diagram for an exemplary execution sequence/instructions and protocol for a dynamic health check/testing, which is performed on a periodic basis, according to yet another aspect of the present disclosure. In this aspect, the flow diagram shows the activities of the dynamic health check. The instructions for the dynamic health check/testing may be stored on a non-transitory memory device on an SoC package. During this dynamic health check, an SoC-level IP will instruct a die's SBO to stop the data traffic, and a die-to-die interconnect IP will take control of the lanes and send specific patterns from one die to another die, as part of link-level testing, which is similar to the patterns sent in during an initial HVM health check. After the pattern generation and comparison, any status of a lane that becomes faulty or non-working during run time will get stored in a health check result register and the present algorithm discards the lane as a substitute lane or for use in the next cyclic rotation of good lanes, and this process continues.

As shown in FIG. 7, a cold boot sequence is sent to a SoC package in activity 711. For example, there may be resets that are de-asserted, clocks started and stabilized, register values are read, assert pwrgood, D2D handshakes, and various training routines may be run.

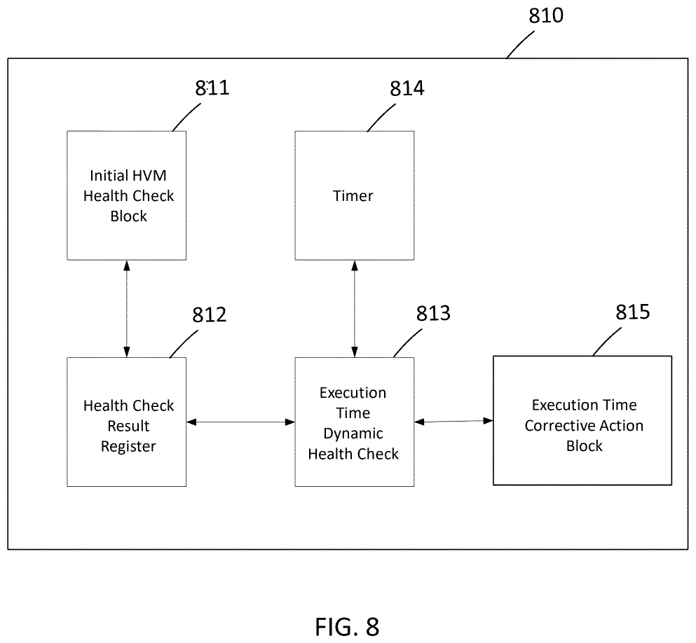

In activity 712, there may be a download from an HVM health check result register, as shown in FIG. 8, which will provide data on the number of available working (i.e., good) lanes. These data values are only read once after a cold boot sequence to program the lanes initially. When both die send CFG_DONE, the dies are ready to start data traffic and a periodic training count value is initialized to 0.

In activity 713, there is a monitoring of the periodic training count to determine when the count reaches “N”, which may be a pre-set value in milliseconds (ms). Until count N is reached, the data traffic remains uninterrupted and follows to activity 718, with periodic checks at 1 ms as shown in activity 719, and monitoring of the data traffic and updating of the periodic training count as shown in activity 720.

In activity 714, when the count N is reached, a signal is relayed by the system box to the SoC level agent to stall/stop the data traffic. The periodic training will begin along with the dynamic health check. Thereafter, in activity 715, a dynamic health check may begin by running a dynamic local die health check that includes:
a. providing fix data patterns, e.g., 0x2_AAAA_AAAA, 0x1_5555_555, which are sent multiple times between dies;
b. monitoring the patterns for outputs within a fixed and certain period from the dies;
c. writing lane status in a health check results register based on the sending of the data patterns;
d. stopping the sending of the data patterns to the dies;
e. reading the lane status from the health check results register, and programming/selecting the lanes for the die-to-die interconnect; and
f. resetting the periodic training count value to 0.

In activity 716, a dynamic health check may begin by running a dynamic link level health check that includes:
a. providing fix data patterns, e.g., 0x2_AAAA_AAAA, 0x1_5555_555, which are sent multiple times between dies;
b. monitoring the patterns for outputs within a fixed and certain period from the dies;
c. writing lane status in a health check results register based on the sending of the data patterns; and
d. stopping the sending of the data patterns to the dies.

If the health check shows that the number of working lanes is less than the required number of working lanes for a die-to-die interconnect, i.e., fails, an interrupt signal is sent to the SoC level agent, and the SoC may alert a system user and discontinue using the SoC package, as represented by activity 721.

In activity 717, if the health check shows that the number of working lanes is sufficient for a die-to-die interconnect, i.e., passes, the lane status is entered into the health check results register and read for the programming/selecting of the lanes for the die-to-die interconnect. Thereafter, in activity 718, the data traffic resumes with periodic checks at 1 ms, as shown in activity 719, and monitoring of the data traffic and updating of the periodic training count as shown in activity 720.

FIG. 8 shows an exemplary representation of a schematic view for a lane controller logic 810 according to an aspect of the present disclosure. The lane controller logic 810 may be coupled with die-to-die interconnect IP boxes associated with the dies (not shown). It should be understood that the lane controller logic 810 may include circuits such as switches, clocks, flip-flops, bi-stables, counters, memories, registers, and other circuit components.

In this aspect, the logic block 811 may provide an initial HVM health check, either on a partial or complete basis, for a chip package, including a Sort/Class, to determine if the dies are working properly and identify the working and non-working lanes of the die-to-die interconnects.

In this aspect, the logic block 812 may be a health check result register, which is coupled to the logic health check block 811. The result of the initial HVM health check in HVM will be stored in logic block 812. The logic block 812 will show all working lanes from the initial HVM health check results as being available, if no faulty or non-working are uncovered, and will not require the active working lanes to be directly fused by the die-to-die interconnect IP, which is unlike a convention HVM health check method.

In this aspect, the logic block 813 may provide for a dynamic health check operation, which may use a similar or the same health check protocol as the initial HVM health check. In an aspect, the logic block 813 may perform this operation with or without any external software/agent support.

In this aspect, the logic block 814 may be a timer that will continuously run in the background, and when the time reaches a certain pre-determined value, a die-to-die interconnect IP requests an SBO for a SoC, as shown above, to stop the data traffic for a designated window, e.g., N equal to 100 milliseconds, using a stall process, as discussed in FIG. 7 above. It should be understood that the value for N may be set according to the application of a die and the need for training/resets. The stall is an indication to the SoC agent to stop the data traffic for the logic block 813 to provide the dynamic health check operation. After the dynamic health check, the result will be stored back in the health check result register 812.

In this aspect, the logic block 815 may be an execution time corrective action (ETCA) circuit (i.e., a switcher) that will take control and perform a lane discarding or switching operation based on the health check result register. For example, if no new lane is found to be faulty during the dynamic health check, the ETCA block 815 may continue to use the current working lane or switch the working lanes in a rotative manner. When a rotational modality is being employed, one of the lanes that was active in the previous cycle may go to IDLE and another “good” working lane will be used. As such, all the good working lanes will get an IDLE period when no data traffic will flow through that lane, which may help avoid overstressing the working lanes. If a faulty lane is found during the dynamic health check, the faulty lane may be unavailable for future use, i.e., deactivated, by the die-to-die IP during this step. During the next iteration of the dynamic health check, the deactivated lanes need not be checked again. Thereafter, the ETCA block 815 is done with the operation, the top-level SoC stall will be removed and normal data traffic will resume.

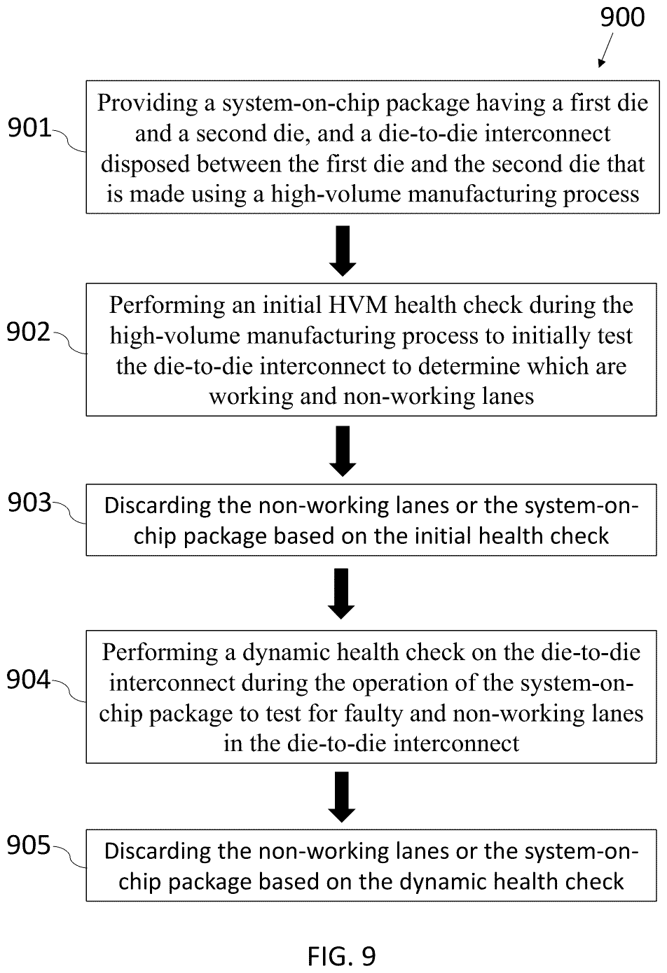

FIG. 9 shows a simplified flow diagram for an exemplary method 900 according to an aspect of the present disclosure.

The operation 901 may be directed to providing a system-on-chip package having a first die and a second die, and a die-to-die interconnect disposed between the first die and the second die that is made using a high-volume manufacturing process.

The operation 902 may be directed to performing an initial HVM health check during the high-volume manufacturing process to initially test the die-to-die interconnect to determine which are working and non-working lanes.

The operation 903 may be directed to discarding the non-working lanes or the system-on-chip package based on the initial health check.

The operation 904 may be directed to performing a dynamic health check on the die-to-die interconnect during the operation of the system-on-chip package to test for faulty and non-working lanes in the die-to-die interconnect.

The operation 905 may be directed to discarding the non-working lanes or the system-on-chip package based on the dynamic health check.

It will be understood that any property described herein for a particular system-on-chip (SoC) package and method for monitoring and controlling the lanes of a die-to-die interconnect may also hold for any SoC using the present die-to-die interconnect described herein. It will also be understood that any property described herein for a specific method may hold for any of the methods described herein. Furthermore, it will be understood that for any die-to-die interconnect and the methods described herein, not necessarily all the components or operations described will be shown in the accompanying drawings or method, but only some (not all) components or operations may be disclosed.

To more readily understand and put into practical effect the monitoring and controlling of the lanes of the present die-to-die interconnects, they will now be described by way of examples. For the sake of brevity, duplicate descriptions of features and properties may be omitted.

### EXAMPLES

Example 1 provides a testing system including a first health check module disposed on a first die and a second health check module disposed on a second die, for which the first die and the second die have a die-to-die interconnect disposed therebetween. In an aspect, the first and second health check modules are configured to perform an initial health check testing of the die-to-die interconnect for working lanes and non-working lanes during high-volume manufacturing of a chip package containing the first and second dies, and a first logic circuit is disposed on the first die and a second logic circuit is disposed on the second die, for which the first logic circuit and the second logic circuit are coupled to the die-to-die interconnect, In another aspect, the first and second logic circuits are configured to perform a dynamic testing of the die-to-die interconnect for working lanes and faulty lanes during operation of the chip package.

Example 2 may include the testing system of example 1 and/or any other example disclosed herein, for which the first and second health check modules are further configured to provide a health check result indicating whether a number of working lanes is less than a required minimum number of working lanes for the chip package, and the testing system is configured to designate the chip package to be discarded if the health check result indicates that the number of working lanes is less than the required minimum number of working lanes.

Example 3 may include the testing system of example 1 and/or any other example disclosed herein, for which the first and second health check modules are further configured to provide a health check result indicating whether a number of working lanes is greater than a required minimum number of working lanes for the chip package, and the testing system is configured to provide instructions to use all of the working lanes of the die-to-die interconnect and not to use the non-working lanes of the die-to-die interconnect.

Example 4 may include the testing system of example 1 and/or any other example disclosed herein, for which the first and second logic circuits are configured to provide the dynamic testing of the die-to-die interconnect on a periodic basis.

Example 5 may include the testing system of example 4 and/or any other example disclosed herein, for which the first and second logic circuits are configured to provide the dynamic testing of the die-to-die interconnect on a periodic basis to coincide with a periodic training of the chip package.

Example 6 provides a system-on-chip package including a first die, a second die, and a die-to-die interconnect disposed therebetween, a health check module configured to provide a health check result for the die-to-die interconnect during high-volume manufacturing of the system-on-chip package, for which the health check result indicates working lanes and non-working lanes for the die-to-die interconnect. In an aspect, the first die includes a first logic circuit coupled to the die-to-die interconnect, and the second die includes a second logic circuit coupled to the die-to-die interconnect, for which the first and second logic circuits are configured to perform a dynamic testing of the die-to-die interconnect for working lanes and faulty lanes during an operation of the system-on-chip package, and for which the first and second logic circuits are further configured to provide instructions that are stored in a non-transitory memory device to control use of the working lanes of the die-to-die interconnect.

Example 7 may include the system-on-chip package of example 6 and/or any other example disclosed herein, for which the first and second logic circuits further include an initial HVM health check block, a health check result register, a timer, an execution time dynamic health check/testing, and an execution time corrective action block.

Example 8 may include the system-on-chip package of example 6 and/or any other example disclosed herein, for which the health check result indicates that a number of working lanes is greater than a required minimum number of working lanes for the system-on-chip package, and the first and second logic circuits are configured to provide instructions to use all of the working lanes of the die-to-die interconnect on a rotational basis.

Example 9 may include the system-on-chip package of example 6 and/or any other example disclosed herein, for which the health check result indicates a number of working lanes is greater than or in excess of a required minimum number of working lanes for the system-on-chip package, and the first and second logic circuits are configured to provide instructions to use all of the working lanes of the die-to-die interconnect by having the working lanes in excess of the required minimum number of working lanes on stand-by as replacement lanes for a faulty lane uncovered during the dynamic testing of the die-to-die interconnect.

Example 10 may include the system-on-chip package of example 6 and/or any other example disclosed herein, for which the first and second logic circuits are configured to provide the dynamic testing of the die-to-die interconnect on a periodic basis.

Example 11 may include the system-on-chip package of example 10 and/or any other example disclosed herein, for which the first and second logic circuits are configured to provide the dynamic testing of the die-to-die interconnect on the periodic basis to coincide with a periodic training of the system-on-chip package.

Example 12 may include a method that provides a system-on-chip package using a high-volume manufacturing process, for which the system-on-chip package includes a first die, a second die, and a die-to-die interconnect disposed therebetween, for which the first die includes a first health check module and a first logic circuit and the second die includes a second health check module and a second logic circuit. In an aspect, the method includes performing an initial health check on the die-to-die interconnect during the high-volume manufacturing process using the first and second health check modules, for which the initial health check includes an initial testing of the die-to-die interconnect to determine which are working lanes and non-working lanes, if any, and obtaining an initial health check result identifying and indicating numbers for working and non-working lanes, and placing the initial health check result in a health check result register, and performing a dynamic health check/testing on the die-to-die interconnect during an operation of the system-on-chip package using the first and second logic circuits, for which the dynamic health check/testing includes a periodic testing of the die-to-die interconnect to determine working lanes and faulty lanes in the die-to-die interconnect and obtaining an updated health check result identifying and indicating numbers for working and faulty lanes, and placing the updated health check result in the health check result register.

Example 13 may include the method of example 12 and/or any other example disclosed herein, for which performing the initial health check further includes obtaining data regarding a required minimum number of working lanes for the die-to-die interconnect needed during the operation of the system-on-chip package and providing instructions to compare the number of working lanes shown by the initial health check result with the required minimum number of working lanes for the die-to-die interconnect.

Example 14 may include the method of example 13 and/or any other example disclosed herein, which further includes discarding the system-on-chip package when the initial health check result shows that the number of working lanes is less than the required minimum number of working lanes for the die-to-die interconnect needed during the operation of the system-on-chip package, and foregoing any further use or checks for the system-on-chip package.

Example 15 may include the method of example 13 and/or any other example disclosed herein, further includes discarding the non-working lanes when the initial health check result shows that the number of working lanes is greater than or equal to the required minimum number of working lanes for the die-to-die interconnect needed during the operation of the system-on-chip package and foregoing the dynamic health checks/testing on the discarded non-working lanes, for which the number of working lanes that are greater than the required minimum number of working lanes for the die-to-die interconnect needed during the operation of the system-on-chip package are designated as excess lanes in the health check result.

Example 16 may include the method of example 15 and/or any other example disclosed herein, further includes using all of the working lanes, including the excess lanes, on a rotational basis during the operation of the system-on-chip package when the initial health check result shows that the number of working lanes is greater than or in excess of the required minimum number of working lanes for the die-to-die interconnect needed during the operation of the system-on-chip package.

Example 17 may include the method of example 16 and/or any other example disclosed herein, which further includes using the required minimum number of working lanes and maintaining the excess lanes in reserve when the initial health check result shows that the number of working lanes is greater than or in excess of the required minimum number of working lanes for the die-to-die interconnect needed during the operation of the system-on-chip package.

Example 18 may include the method of example 12 and/or any other example disclosed herein, which further includes using one or more of the excess lanes to replace one or more of the required minimum number of working lanes when the dynamic health check/testing uncovers one or more faulty or non-working lanes among the required minimum number of working lanes.

Example 19 may include the method of example 18 and/or any other example disclosed herein, which further includes providing a user notification and/or deactivating the die-to-die interconnect in the system-on-chip package when there is no excess lane to replace one of the required minimum number of working lanes after the dynamic health check/testing uncovers a faulty or non-working lane among the required minimum number of working lanes.

Example 20 may include the method of example 12 and/or any other example disclosed herein, for which the periodic testing of the die-to-die interconnect for the dynamic health check/testing coincides with a periodic training of the system-on-chip package.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A testing system comprising:
a first health check module disposed on a first die and a second health check module disposed on a second die, wherein the first die and the second die have a die-to-die interconnect disposed therebetween;
wherein the first health check module and second health check module are configured to perform an initial health check testing of the die-to-die interconnect for working lanes and non-working lanes during high-volume manufacturing of a chip package containing the first die and the second die; and
a first logic circuit disposed on the first die and a second logic circuit disposed on the second die, wherein the first logic circuit and the second logic circuit are coupled to the die-to-die interconnect;
wherein the first and second logic circuits are configured to perform a dynamic testing of the die-to-die interconnect for working lanes and faulty lanes during operation of the chip package.

2. The testing system of claim 1, wherein the first and second health check modules are further configured to provide a health check result indicating whether a number of working lanes is less than a required minimum number of working lanes for the chip package, and the testing system is configured to designate the chip package to be discarded if the health check result indicates that the number of working lanes is less than the required minimum number of working lanes.

3. The testing system of claim 1, wherein the first and second health check modules are further configured to provide a health check result indicating whether a number of working lanes is greater than a required minimum number of working lanes for the chip package, and the testing system is configured to provide instructions to use all of the working lanes of the die-to-die interconnect and not to use the non-working lanes of the die-to-die interconnect.

4. The testing system of claim 1, wherein the first and second logic circuits are configured to provide the dynamic testing of the die-to-die interconnect on a periodic basis.

5. The testing system of claim 4, wherein the first and second logic circuits are configured to provide the dynamic testing of the die-to-die interconnect on a periodic basis to coincide with a periodic training of the chip package.

6. A system-on-chip package comprising:
a first die, a second die, and a die-to-die interconnect disposed therebetween;
a health check module configured to provide a health check result for the die-to-die interconnect during high-volume manufacturing of the system-on-chip package, wherein the health check result indicates working and non-working lanes for the die-to-die interconnect;
wherein the first die comprises a first logic circuit coupled to the die-to-die interconnect, and the second die comprises a second logic circuit coupled to the die-to-die interconnect, wherein the first and second logic circuits are configured to perform a dynamic testing of the die-to-die interconnect for working lanes and faulty lanes during an operation of the system-on-chip package; and
wherein the first and second logic circuits are further configured to provide instructions that are stored in a non-transitory memory device to control use of the working lanes of the die-to-die interconnect.

7. The system-on-chip package of claim 6, wherein each of the first and second logic circuits further comprise:
an initial HVM health check block;
a health check result register;
a timer;
an execution time dynamic health check; and
an execution time corrective action block.

8. The system-on-chip package of claim 6, wherein the health check result indicates that a number of working lanes is greater than a required minimum number of working lanes for the system-on-chip package, and the first and second logic circuits are configured to provide instructions to use all of the working lanes of the die-to-die interconnect on a rotational basis.

9. The system-on-chip package of claim 6, wherein the health check result indicates a number of working lanes is greater than or in excess of a required minimum number of working lanes for the system-on-chip package, and the first and second logic circuits are configured to provide instructions to use all of the working lanes of the die-to-die interconnect by having the working lanes in excess of the required minimum number of working lanes on stand-by as replacement lanes for a faulty lane uncovered during the dynamic testing of the die-to-die interconnect.

10. The system-on-chip package of claim 6, wherein the first and second logic circuits are configured to provide the dynamic testing of the die-to-die interconnect on a periodic basis.

11. The system-on-chip package of claim 10, wherein the first and second logic circuits are configured to provide the dynamic testing of the die-to-die interconnect on the periodic basis to coincide with a periodic training of the system-on-chip package.

12. A method comprising:
providing a system-on-chip package using a high-volume manufacturing process, wherein the system-on-chip package comprises a first die, a second die, and a die-to-die interconnect disposed therebetween, wherein the first die comprises a first health check module and a first logic circuit and the second die comprises a second health check module and a second logic circuit;
performing an initial health check on the die-to-die interconnect during the high-volume manufacturing process using the first and second health check modules, wherein the initial health check comprises an initial testing of the die-to-die interconnect to determine which are working lanes and non-working lanes, if any, and obtaining an initial health check result identifying and indicating numbers for working and non-working lanes, and placing the initial health check result in a health check result register; and
performing a dynamic health check on the die-to-die interconnect during an operation of the system-on-chip package using the first and second logic circuits, wherein the dynamic health check comprises a periodic testing of the die-to-die interconnect to determine working lanes and faulty lanes in the die-to-die interconnect and obtaining an updated health check result identifying and indicating numbers for working and faulty lanes, and placing the updated health check result in the health check result register.

13. The method of claim 12, wherein performing the initial health check further comprises obtaining data regarding a required minimum number of working lanes for the die-to-die interconnect needed during the operation of the system-on-chip package and providing instructions to compare the number of working lanes shown by the initial health check result with the required minimum number of working lanes for the die-to-die interconnect.

14. The method of claim 13, further comprises discarding the system-on-chip package when the initial health check result shows that the number of working lanes is less than the required minimum number of working lanes for the die-to-die interconnect needed during the operation of the system-on-chip package, and foregoing any further use or checks for the system-on-chip package.

15. The method of claim 13, further comprises discarding the non-working lanes when the initial health check result shows that the number of working lanes is greater than or equal to the required minimum number of working lanes for the die-to-die interconnect needed during the operation of the system-on-chip package and foregoing the dynamic health checks on the discarded non-working lanes, wherein the number of working lanes that are greater than the required minimum number of working lanes for the die-to-die interconnect needed during the operation of the system-on-chip package are designated as excess lanes in the health check result.

16. The method of claim 15, further comprises using all of the working lanes, including the excess lanes, on a rotational basis during the operation of the system-on-chip package when the initial health check result shows that the number of working lanes is greater than or in excess of the required minimum number of working lanes for the die-to-die interconnect needed during the operation of the system-on-chip package.

17. The method of claim 15, further comprises using the required minimum number of working lanes and maintaining the excess lanes in reserve when the initial health check result shows that the number of working lanes is greater than or in excess of the required minimum number of working lanes for the die-to-die interconnect needed during the operation of the system-on-chip package.

18. The method of claim 17, further comprises using one or more of the excess lanes to replace one or more of the required minimum number of working lanes when the dynamic health check uncovers one or more faulty or non-working lanes among the required minimum number of working lanes.

19. The method of claim 18, further comprises providing a user notification and/or deactivating the die-to-die interconnect in the system-on-chip package when there is no excess lane to replace one of the required minimum number of working lanes after the dynamic health check uncovers a faulty or non-working lane among the required minimum number of working lanes.

20. The method of claim 12, wherein the periodic testing of the die-to-die interconnect for the dynamic health check coincides with a periodic training of the system-on-chip package.
